(19) United States
(12) Patent Application Publication
(10) Pub. No.: US 2008/0068791 A1
(43) Pub. Date: Mar. 20, 2008

(54) Equipment and Network Cabinet

(75) Inventor: Heiko Ebermann, Dresden (DE)

Correspondence Address: HARNESS, DICKEY & PIERCE, P.L.C., P.O. BOX 828, BLOOMFIELD HILLS, MI, 48303, US

(73) Assignee: Knurr AG, Arnstorf (DE)

(21) Appl. No.: 11/665,231

(22) PCT Filed: Aug. 29, 2005
(86) PCT No.: PCT/EP05/09298

§ 371 Date: May 11, 2007

(30) Foreign Application Priority Data
Oct. 25, 2004 (DE) 20 2004 016 492.2

(51) Int. Cl. H05K 7/20

(52) U.S. Cl. 361/687

(57) ABSTRACT

The invention relates to an equipment and network cabinet or a housing for receiving electronic modular units, particularly a server cabinet, which has a substantially airtight construction and has a closed cooling air circuit with a heat exchanger for thermal power loss dissipation. In order to be able to recirculate without increased pressure losses the air mass flows circulated at an increased flow rate, flow-correct components are provided which reduce the flow resistance in the cooling air circuit and lead to an optimization and deflection of the air flow.

The invention relates to an equipment and network cabinet according to the preamble of claim 1.

The invention is particularly suitable for server cabinets, in which a plurality of servers as electronic modular units are superimposed or also juxtaposed. Servers, particularly the compact constructions of e.g. a height unit (U), such as a pizzabox and blade server, are subject to significant power dissipations. In order to dissipate the heat it is known to place the electronic modular units in a housing with at least one fan, together with air inlets and air outlets.

It is known to construct equipment and network cabinets, particularly server cabinets, in a largely airtight manner and to provide a closed cooling air circuit and a heat ex-changer for removing the thermal power losses. DE 20 2004 006 552.5 uses an air-water heat exchanger to which is supplied via an outlet air duct the outlet air heated by the electronic modular units. The inlet air cooled in the heat exchanger passes via an inlet air duct to the electronic modular units.

The rising power levels of electronic components, such as process computers and servers are linked with constantly increasing heat losses. As a result of the very high and constantly further increasing thermal power losses within the equipment and net-work cabinets or server cabinets ever higher air mass flows are required. However, the cross-sections of the air ducting cabinet parts can only be increased to a very limited extent, so that there is a rise in the flow rates of the air within the cabinet or housing. With this is associated a considerable increase in the pressure loss of the cooling air which is recirculated.

At the same time the installation space for fans only exists to a limited extent. Also for noise protection reasons fans with increased hydraulic power levels can only be used to a limited extent. Increased pressure differences between the cabinet or housing also leads to higher demands with respect to the airtight construction of the cabinet or housing construction.

The object of the invention is to provide an equipment and network cabinet or a housing for receiving electronic modular units, in which the disadvantages associated with an increased flow rate of the cooling air circuit are largely avoided.

According to the invention the object is achieved by the features of claim 1. Appropriate and advantageous embodiments are given in the subclaims and the specific description relative to the drawings.

It is a fundamental idea of the invention to reduce the increased pressure losses resulting from an increased cooling air flow rate. According to the invention the flow resistance in the cooling air circuit is reduced by flow-correct components. The term flow-correct components is understood to mean all components which are used for optimizing, guiding and deflecting the air flow.

Advantageously as flow-correct components are provided elements for deflecting the air flow which is recirculated. Deflecting elements can e.g. be in the form of air or guide vanes, radii and baffle plates, which are preferably located in areas of the cooling air circuit in which the inlet air and/or outlet air is subject to a significant direction change, e.g. a 90° deflection.

Such deflection areas are formed more particularly upstream and downstream of a heat exchanger. If air vanes and radii are arranged in a defined manner in these deflection areas there is an improvement of the flow through due to reducing the flow resistance.

Advantageously a heat exchanger, e.g. an air-water heat exchanger, is arranged in a bottom-side area of a cabinet or housing and is connected to a substantially vertically oriented inlet air duct for the inlet air cooled in the heat exchanger and with an outlet air duct for the supply of the outlet air heated by the electronic modular units. Appropriately the deflection areas provided upstream and downstream of the heat exchanger are provided with the flow-correct components, particularly air vanes and radii.

It is particularly advantageous that the flow-correct components can be integrated into a deflection device, which can be preassembled. Such a deflection device can then be secured in the cabinet or housing, e.g. on panelling parts such as side walls, front or rear door.

If an outlet air duct is formed in a rear door, the associated deflection device can also be more particularly detachably fastened in the door. The air vanes are preferably arcuate and have an almost identical design and can in particular be arranged in offset super-imposed manner, e.g. on an imaginary diagonal over the entire cross-section of the deflection area.

The radii are appropriately provided for bridging a roughly right-angled corner area of the cabinet or a panelling part and are in particular arcuately designed in the same way as the air vanes.

Particularly in the inlet air duct it is appropriate for the planned supply of individual electronic modular units with cooled inlet air to provide baffle plates as flow-correct components. If said baffle plates can be detachably fixed, it is possible with limited effort to arrange the same in the in each case necessary, predeterminable position.

Appropriately the baffle plates have a spoiler-like construction and are provided with an impact surface for the inlet air, which is formed close to the reception area or the electronic modular units to be cooled.

The invention is described in greater detail hereinafter relative to the attached highly diagrammatic drawings, wherein show:

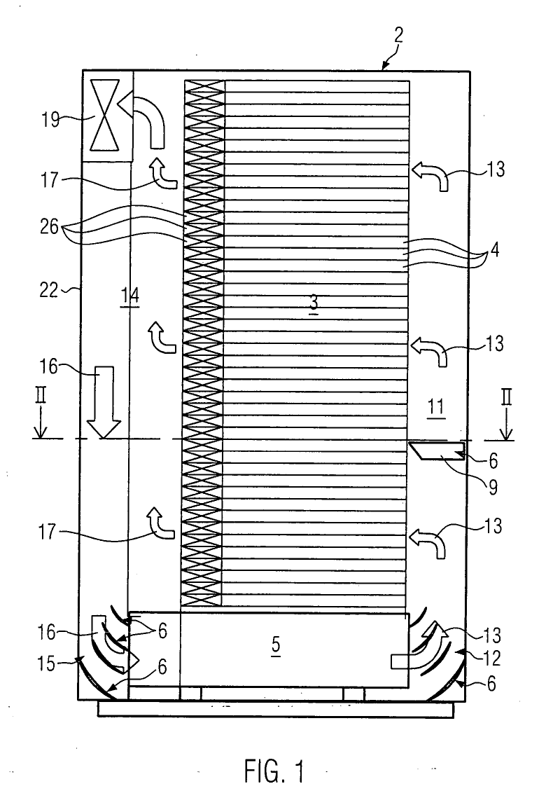

FIG. 1A longitudinal section through an inventive equipment and network cabinet.

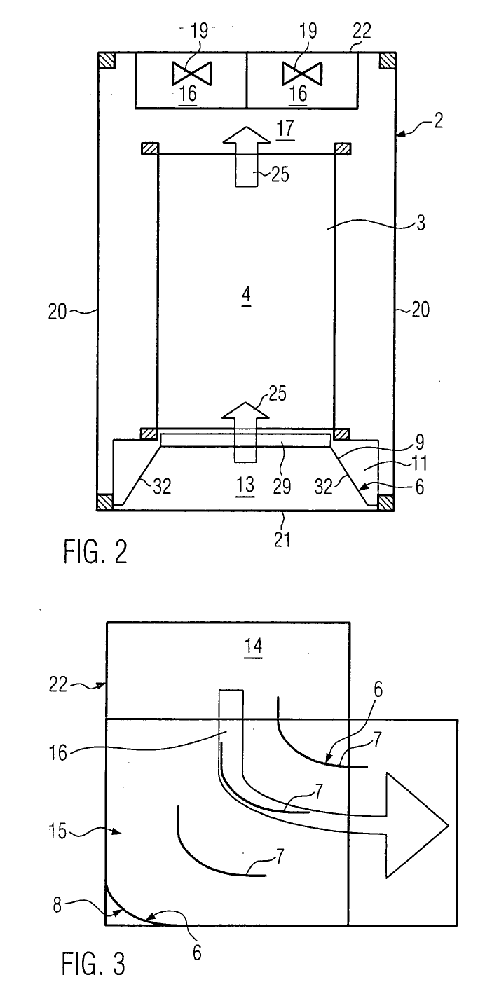

FIG. 2A cross-section through the inventive equipment and network cabinet along line II-II in FIG. 1.

FIG. 3A larger scale representation of the outlet air deflection area of FIG. 1.

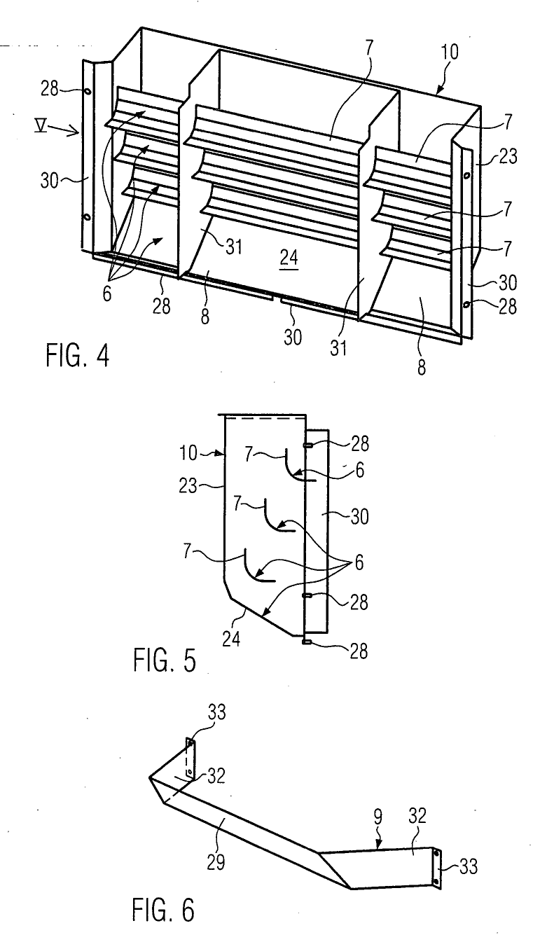

FIG. 4A perspective view of a deflection device.

FIG. 5A side view of the deflection device along arrow V in FIG. 4

FIG. 6A perspective view of a baffle plate.

A server cabinet is shown in highly diagrammatic form in FIGS. 1 and 2 as equipment or network cabinet 2. In a largely airtight inner area 3 are superimposed in stack-like form servers as electronic modular units 4 and their heat loss is removed with the aid of a closed cooling air circuit and a heat exchanger 5.

The heat exchanger 5 is an air-water heat exchanger, which is connected to a vertically oriented inlet air duct 11 and a vertically oriented outlet duct 14. In this embodiment the inlet air duct 11 is constructed over virtually the entire height of cabinet 2 and has, considered in the flow direction, downstream of the heat exchanger 5 a deflection area 12 with flow-correct components 6. Inlet air 13 from the inlet air duct 11 is supplied to the electronic modular units 4 located in the housings and in this embodiment use is made of fans 26. The air flow in the vicinity of the electronic modular units 4 is illustrated by arrows 25 in FIG. 2. In principle, the fans 26 associated with the electronic modular unit 4 shown in FIG. 1 are unnecessary, because in the vicinity of the outlet air duct 14 fans 19 are provided, which suck the outlet air from the electronic modular units 4 in a first duct section and initially impose a rising outlet air flow 17 and then a parallel, falling outlet flow 16. In a deflection area 15 the outlet air 16 undergoes a 90° direction change and enters the bottom-side heat exchanger 5.

To reduce the flow resistance and the pressure losses in the cooling air circuit flow-correct components 6, particularly air vanes 7 and radii 8 (cf. FIGS. 3 to 5) are positioned in the outlet air-side deflection area 15. FIG. 1 illustrates that in the same way as with the deflection area 15 for outlet air 16, there is also a deflection area 12 for the cooled inlet air 13 which has been subject to a virtually right-angled deflection and which passes out of the heat exchanger 5 and which is equipped with flow correct components 6.

FIG. 3 shows on a larger scale the outlet air-side deflection area 15. Coinciding with FIG. 1 the outlet air-side deflection area 15 is constructed in a panelling part 20 of cabinet 2, in the present embodiment in the rear door 22. A radius 8 covers a corner area of rear door 22 and has an arcuate or crescent-shaped design. As further flow-correct components there are three air vanes 7 in the deflection area 15 and are essentially identically arcuately or crescent-shaped constructed and are fixed to one another with a roughly identical spacing in the diagonal direction. As a result of the design it is possible to significantly reduce the flow resistance in said deflection area, so that the pressure losses at a necessary air speed can be minimized. It is possible to provide a random number of air vanes 7.

FIGS. 4 and 5 show a deflection device 10 in which are integrated the flow-correct components 6. The advantageously retrofittable and/or preassemblable deflection device 10 has in this embodiment three to each other offset arranged air vanes 7 and a bottom-side radius 8 and which are located in a housing 23. The housing 23 has an open construction in the direction of the inlet air duct 11 or outlet air duct 14 and in the direction of the heat exchanger 5. Fastening elements 28 on wall-side flanges 30 can be constructed for detachable fastening of the deflection device 10, e.g. in the form of slot or keyhole openings or as hang-in fastening pins. Vertically oriented partitions 31 are used for fastening the offset, superimposed, arcuate air vanes 7 and can be positioned so as to coincide with the vertically constructed partial ducts for the falling outlet air flow 16.

FIG. 6 shows a baffle plate 9 located in the inlet air duct 11 (FIGS. 1 and 2). Said baffle plate 9 is advantageously produced from a blank and has a sloping impact surface 29 and bilateral fastening arms 32 with angled fastening webs 33 for an advantageous, detachable fastening to a panelling part, e.g. to a front door 21. FIGS. 1 and 2 make it clear that impact surface 29 is positioned close to the stack arrangement of electronic modular units 4, so that the inlet air 13 can be deflected by the impact surface 29 in the direction of an electronic modular unit 4 in order to bring about an increased power dissipation.

1.-14. (canceled)

15. Equipment and network cabinet, particularly server cabinet, with an inner area in which are located electronic modular units, and a closed cooling air circuit with an inlet air duct, an outlet air duct and a heat exchanger positioned between them for removing from cabinet the heat losses of the electronic modular units, wherein for reducing the flow resistance flow-correct components are provided in the inlet air duct and/or outlet air duct which are constructed as air vanes and radii and are placed in a deflection device, which is preassemblable and/or retrofittable.

16. Cabinet according to claim 15, wherein for optimizing, guiding and deflecting the air flow, the deflection device is located in deflection areas of the inlet air for the electronic modular units and/or in deflection areas of the outlet air for the electronic modular units.

17. Cabinet according to claim 15, wherein in addition to the air vanes and radii, baffle plates are located as flow-correct components in the cooling air circuit.

18. Cabinet according to claim 15, wherein close to the heat exchanger, which is located on the bottom side between a vertically oriented inlet air duct and a vertically oriented outlet air duct, a deflection area for the inlet air supplied to inlet air duct and which is cooled in the heat exchanger and/or a deflection area for the outlet air supplied to the heat exchanger in the outlet air duct and which has been heated by the electronic modular units are provided and the deflection device is located therein.

19. Cabinet according to claim 15, wherein the outlet air duct has a first duct section for rising, outlet air flow and subsequently a second duct section for a falling outlet air flow, that the second duct section for the falling outlet air flow is constructed in a paneling part of the cabinet, particularly in a rear door and the deflection device for the outlet air to be supplied to the heat exchanger is positioned.

20. Cabinet according to claim 15, wherein the air vanes arranged as flow-correct components in longitudinal section are orbital—arcuately designed for a deflection of almost 90° and more of the inlet air or for a deflection of the outlet air from the electronic modular units.

21. Cabinet according to claim 15, wherein the air vanes of the deflection device are almost identically constructed and are arranged in offset, superimposed and in particular uniformly spaced manner from each other on a diagonal.

22. Cabinet according to claim 15, wherein the radii provided as flow-correct components in each case are designed as a beveled or rounded plate and to bridge a right-angled corner area of the cabinet and/or a door.

23. Cabinet according to claim 15, wherein the deflection devices are given a casing-like construction and are designed in open manner in the direction of the adjacent heat exchanger and inlet air duct or outlet air duct and that the bottom-side radii are in each case designed as beveled, downwardly directed housing bottom.

24. Cabinet according to claim 17, wherein the baffle plates for the planned supply of individual electronic modular units with inlet air cooled in the heat exchanger are provided in the inlet air duct.

25. Cabinet according to claim 24, wherein the baffle plates are fixed in detachable manner and in a predeterminable height on the wall of the inlet air duct.

26. Cabinet according to claim 24, wherein the baffle plates have a spoiler-like design and are provided with an impact surface arranged in diametral manner to the inlet air flow.

27. Cabinet according to claim 24, wherein baffle plates have an impact surface, which represents approximately one third to one quarter of the cross-sectional surface of the inlet air duct.

28. Cabinet according to claim 24, wherein the baffle plates are positioned in such a way that the impact surface is almost adjacent to the electronic modular unit to be cooled.
